(19) United States
(12) Patent Application Publication
(10) Pub. No.: US 2012/0312591 A1
(43) Pub. Date: Dec. 13, 2012

(54) Printed Circuit Board and Method of Manufacturing the Same

(75) Inventors: Sun Uk Hwang, Seoul (KR); Ryoichi Watanabe, Gyunggi-do (KR); Kyung Don Mun, Gyunggi-do (KR)

(73) Assignee: SAMSUNG ELECTRO-MECHANICS CO., LTD., Gyunnggi-do (KR)

(21) Appl. No.: 13/217,589

(22) Filed: Aug. 25, 2011

(30) Foreign Application Priority Data
Jun. 9, 2011 (KR) 1020110055774

(51) Int. Cl. H05K 1/11; H05K 3/00; H05K 1/00

(52) U.S. Cl. 174/266; 174/250; 174/261; 29/829

(57) ABSTRACT

Disclosed herein is a printed circuit board including: an insulating layer including a stopper layer for trench formation disposed in an inner portion thereof and trenches formed to expose the stopper layer for trench formation; and circuit patterns formed in the trenches.

### CROSS REFERENCE TO RELATED APPLICATION

This application claims the benefit of Korean Patent Application No. 10-2011-0055774, filed on Jun. 9, 2011, entitled “Printed Circuit Board And Method Of Manufacturing The Same” which is hereby incorporated by reference in its entirety into this application.

### BACKGROUND OF THE INVENTION

1. Technical Field

The present invention relates to a printed circuit board and a method of manufacturing the same.

2. Description of the Related Art

A printed circuit board is generally formed by forming wirings on one surface or both surfaces of a board made of various thermosetting synthetic resins using a copper wire, fixedly disposing integrated circuits (ICs) or electronic components on the board, implementing electrical wirings between the ICs or the electronic components, implementing the electrical wirings between the ICs or the electronic components, and then coating the electrical wirings using an insulator.

In accordance with the recent development of the electronics industry, a demand for electronic components having a multi-function has rapidly increased, and it has been also demanded that a printed circuit board having these electronic components mounted thereon has high density wirings. Therefore, research into a method of forming a circuit capable of implementing a micro circuit pattern among a process of manufacturing a printed circuit board has been actively conducted.

FIG. 10 is a cross-sectional view showing a structure of the printed circuit board according to the prior art.

Hereinafter, the printed circuit board according to the prior art will be described with reference to FIG. 10.

Referring to FIG. 10, the printed circuit board according to the prior art has a structure in which a circuit layer 30 including a via and a circuit pattern is formed on a copper clad laminate (CCL) 10 including copper clad layers 10b laminated on both surfaces of an insulating layer 10a.

In this configuration, the via and the circuit pattern may be formed by forming a via hole in the CCL 10 and then performing a general plating process including an electroless plating process and an electroplating process on an inner wall of the via hole and the CCL 10.

However, in the case of the printed circuit board according to the prior art as described above, as a width of the circuit pattern is reduced an in a micro circuit pattern portion denoted by A in FIG. 10, an adhesion area between the circuit pattern and the insulating layer is reduced, such that adhesion therebetween is reduced, thereby causing loss of the circuit pattern.

Particularly, when the circuit pattern has a width of 10 μm or less, the adhesion is significantly reduced, such that the above-mentioned problem is easily generated.

### SUMMARY OF THE INVENTION

The present invention has been made in an effort to provide a method of manufacturing a printed circuit board capable of simplifying a process and miniaturizing a product, and a printed circuit board manufactured by the same.

Further, the present invention has been made in an effort to provide a method of manufacturing a printed circuit board capable of implementing a stable micro circuit in which loss of a circuit is not generated, and a printed circuit board manufactured by the same.

According to a first preferred embodiment of the present invention, there is provided a printed circuit board including: an insulating layer including a stopper layer for trench formation disposed in an inner portion thereof and trenches formed to expose the stopper layer for trench formation; and circuit patterns formed in the trenches.

The stopper layer for trench formation may be disposed in a length direction of the insulating layer.

The stopper layer for trench formation may be disposed in plural.

The stopper layer for trench formation may be made of a glass fiber fabric.

The insulating layer may further include vias formed therein, wherein vias penetrate through the stopper layer for trench formation and have a sandglass shape.

The printed circuit board may further include a solder resist layer formed on the insulating layer and having openings exposing some of the circuit patterns and external connection terminals formed on the circuit patterns exposed by the openings, wherein the external connection terminal is a solder ball.

The circuit pattern may be formed of a plating layer.

According to a second preferred embodiment of the present invention, there is provided a method of manufacturing a printed circuit board, the method including: preparing an insulating layer including a stopper layer for trench formation disposed in an inner portion thereof; forming trenches exposing the stopper layer for trench formation in the insulating layer; and forming circuit patterns in the trenches.

The forming of the trenches may be performed by a laser beam, wherein the laser beam is any one of a CO₂ laser and a YAG laser.

The forming of the trenches may further include forming via holes penetrating through the stopper layer for trench formation in the insulating layer, and the forming of the circuit patterns in the trenches may further include forming vias in the via holes.

The trenches and the via holes may be simultaneously formed, and the circuit patterns and the vias may be simultaneously formed.

The via holes may be formed before or after the forming of the trenches, and the circuit patterns and the vias may be simultaneously formed.

The forming of the via holes may be performed by any one of a CO₂ laser, a YAG laser, and a CNC drill.

The forming of the circuit patterns in the trenches may include: forming a plating layer on the insulating layer and the trenches by performing a plating process; and forming circuit patterns by removing the plating layer excessively formed on the insulating layer.

The removing of the plating layer may be performed through chemical polishing, mechanical polishing or chemical mechanical polishing.

The stopper layer for trench formation may be made of a glass fiber fabric.

### BRIEF DESCRIPTION OF THE DRAWINGS

FIG. 1 is a cross-sectional view showing a structure of a printed circuit board according to a preferred embodiment of the present invention;

FIGS. 2 to 8 are cross-sectional views showing a method of manufacturing a printed circuit board according to a preferred embodiment of the present invention in a process sequence;

FIG. 9 is a view showing an insulating layer in which glass fiber fabric serving as stopper layers for trench formation are disposed according to a preferred embodiment of the present invention; and

FIG. 10 is a cross-sectional view showing a structure of the printed circuit board according to the prior art.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted. In the description, the terms “first”, “second”, and the like, are used to distinguish one element from another element, and the elements are not defined by the above terms.

Hereinafter, preferred embodiments of the present invention will be described in detail with reference to the accompanying drawings.

Printed Circuit Board

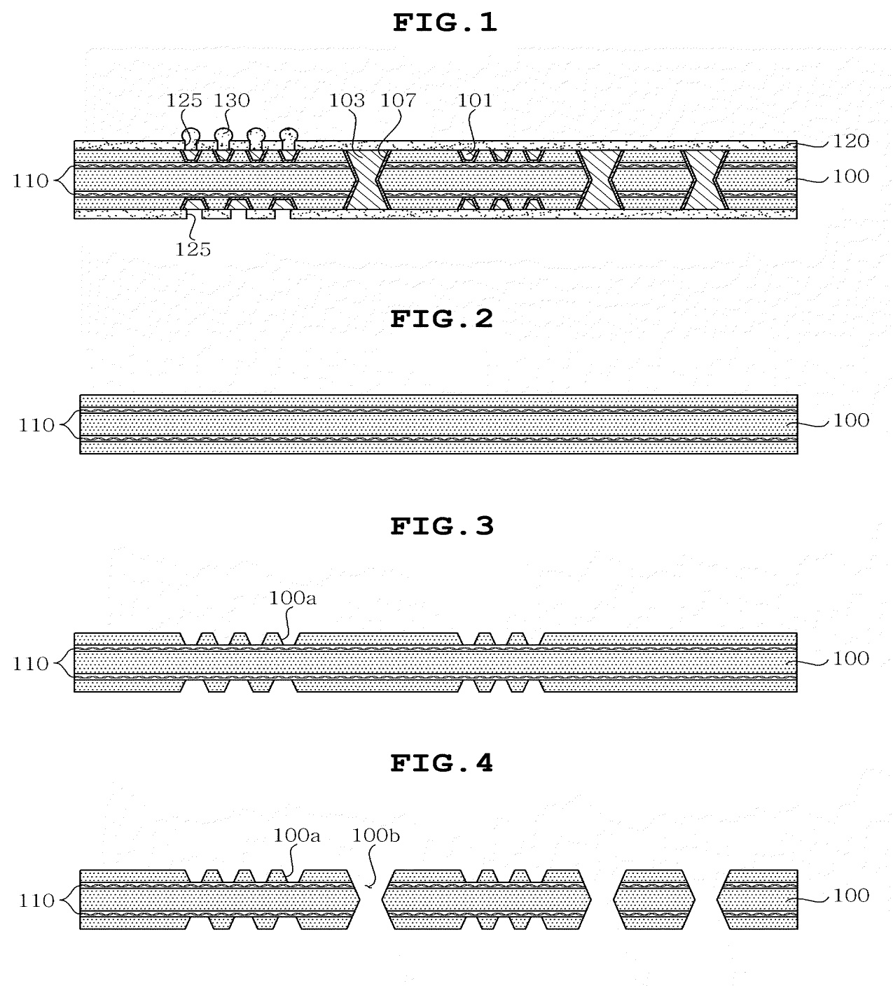

FIG. 1 is a cross-sectional view showing a structure of a printed circuit board according to a preferred embodiment of the present invention.

Referring to FIG. 1, a printed circuit board according to a preferred embodiment of the present invention includes an insulating layer 100 and intagliated circuit patterns 101 and a via 103 that are formed in the insulating layer 100.

According to the preferred embodiment of the present invention, the insulating layer 100, which is a core insulating layer in which copper clad layers are not laminated on both surfaces thereof, includes stopper layers 110 for trench formation disposed in an inner portion thereof.

Here, as the insulating layer 100, a resin insulating layer may be used. As materials of the resin insulating layer, a thermo-setting resin such as an epoxy resin, a thermo-plastic resin such as a polyimide resin, a resin having a reinforcement material such as a glass fiber or an inorganic filler impregnated in them, for example, a prepreg may be used. In addition, a thermo-setting resin, a photo-setting resin, and the like, may be used. However, the materials of the resin insulating layer are not specifically limited thereto.

Although the preferred embodiment of the present invention shows a case in which two stopper layers 110 for trench formation, that is, upper and lower stopper layers 110 for trench formation are disposed in the inner portion of the insulating layer 100 at a predetermined depth from both surfaces thereof as shown in FIG. 1, a single layer stopper layer 110 for trench formation or at least three stopper layers 110 for trench formation may also be disposed.

Here, when at least three stopper layers 110 for trench formation are disposed, a stopper layer 110 for trench formation disposed at the center except for stopper layers 110 for trench formation that are close to the surfaces of the insulating layer 100 may serve as a rigidity member for preventing warpage of a substrate.

In addition, the stopper layers 110 for trench formation that are close to the surfaces of the insulating layer 100 may be disposed in the inner portion of the insulating layer 100 at a depth of about 5 μm from the surfaces thereof, without being specifically limited thereto.

Further, the stopper layers 110 for trench formation may be disposed in the inner portion of the insulating layer 100 in a length direction thereof, as shown in FIG. 1.

According to the preferred embodiment of the present invention, the stopper layer 110 for trench formation, which will be described in detail in the following process step, is a configuration for allowing depths of trenches formed at the time of processing of a trench in the insulating layer 100 using a laser to be uniform.

That is, the stopper layer 110 for trench formation is a configuration for processing trenches having substantially the same depth in order to form uniform circuit patterns.

According to the preferred embodiment of the present invention, the stopper layer 110 for trench formation may be made of a glass fiber fabric, without being specifically limited thereto.

The glass fiber fabric generally serves to maintain mechanical characteristics such as warpage strength, or the like, and dimensional stability with respect to heat, pressure, or the like, in a material for a printed circuit board such as a copper clad laminate, a prepreg, or the like, to thereby allow a process to be performed.

A process of manufacturing the insulating layer 100 in which the stopper layers 110 for trench formation are disposed at an appropriate position thereof according to the preferred embodiment of the present invention will be described in detail below.

The circuit patterns 101 and the via 103 may be formed of a plating layer, without being specifically limited thereto. For example, the circuit patterns 101 and the via 103 may be made of a material such as a conductive paste.

Here, when the circuit patterns 101 and the via 103 are formed of a plating layer, the plating layer may include an electroless plating layer and an electroplating layer.

Although FIG. 1 shows a case in which the circuit patterns 101 are formed on both surfaces of the insulating layer 100, the circuit patterns 101 may also be formed on one of upper and lower surfaces of the insulating layer 100.

According to the preferred embodiment of the present invention, the circuit patterns 101 may be formed so that it has one surface contacting the stopper layer 110 for trench formation, and the via 103 may be formed to penetrate through the stopper layer 110 for trench formation.

In this configuration, the via 103 may have a sandglass shape in which a central portion thereof has a diameter smaller than those of inlet portions provided at upper and lower portions thereof, as shown in FIG. 1.

When a field via method in which the entire inner portion of a via hole 100b shown in FIG. 4 is used in order to form the via 103, a plating layer formed on an upper portion of the insulating layer 100 is generally formed to be thick due to a difference in plating speed between the upper portion of the insulating layer 100 and the inner portion of the via hole 100b. However, the via has the above-mentioned sandglass shape, thereby making it possible to solve this problem.

In addition, the printed circuit board according to the preferred embodiment of the present invention may further include a solder resist layer 120 formed on the insulating layer 100 and having openings 125 exposing some of the circuit patterns 101.

The solder resist layer 120 serves as a protective layer protecting outermost circuits and is formed for electrical insulation. The solder resist layer 120 may be made of, for example, solder resist ink, a solder resist film, an encapsulant, or the like, as known in the art, without being specifically limited thereto.

In addition, external connection terminals 130 for connection to external elements may be formed on the circuit patterns 101 exposed by the openings 125. Here, the external connection terminal 130 may be a solder ball.

Therefore, in the case of the printed circuit board according to the preferred embodiment of the present invention, the trenches are formed in the insulating layer to form the intagliated circuit patterns, such that a phenomenon in which the circuit patterns having a micro width is delaminated from the insulating layer is prevented, thereby making it possible to easily implement a micro circuit.

Further, in the printed circuit board according to the preferred embodiment of the present invention, the stopper layers for trench formation are disposed in the inner portion of the insulating layer to process the trenches having substantially uniform depths, thereby making it possible to form uniform circuit patterns.

Method of Manufacturing Printed Circuit Board

FIGS. 2 to 8 are cross-sectional views showing a method of manufacturing a printed circuit board according to a preferred embodiment of the present invention in a process sequence.

First, as shown in FIG. 2, an insulating layer 100 including stopper layers 110 for trench formation disposed in an inner portion thereof is prepared.

In the preferred embodiment of the present invention, the stopper layer 110 for trench formation may be made of a glass fiber fabric, without being specifically limited thereto.

The glass fiber fabric generally serves to maintain mechanical characteristics such as warpage strength, or the like, and dimensional stability with respect to heat, pressure, or the like, in a material for a printed circuit board such as a copper clad laminate, a prepreg, or the like, to thereby allow a process to be performed.

The glass fiber fabric may be manufactured by twisting a plurality of glass fiber strands having a diameter of about 10 μm to produce glass yarn and then weaving the glass yarn.

Next, the glass fiber fabric manufactured as described above is impregnated in varnish prepared by solving, for example, an epoxy resin in a solvent and then dried. The above-mentioned processes correspond to a general process of manufacturing a prepreg in which the glass fiber fabric is impregnated.

According to the preferred embodiment of the present invention, the glass fiber fabric impregnated in the prepreg is used as the stopper layer 110 for trench formation. The insulating layer 100 including the stopper layer 110 for trench formation disposed in an appropriate portion in the inner portion thereof may be manufactured by controlling a time during which the glass fiber fabric is impregnated in the varnish to thereby control thicknesses of resin layers formed on both surfaces of the glass fiber fabric.

That is, according to a time during which the glass fiber fabric is impregnated in the varnish, for example, when the time is short, the resin layers formed on both surfaces of the glass fiber fabric has a thin thickness, and when the time is long, the resin layers has a thick thickness. Therefore, the glass fiber fabric is impregnated in the varnish only during a time during which the resin layers having a desired thickness may be formed and is then dried, thereby forming the insulating layers.

Here, a thickness of the resin layer on the glass fiber fabric may be about 5 μm from a surface of the glass fiber fabric, without being specifically limited thereto.

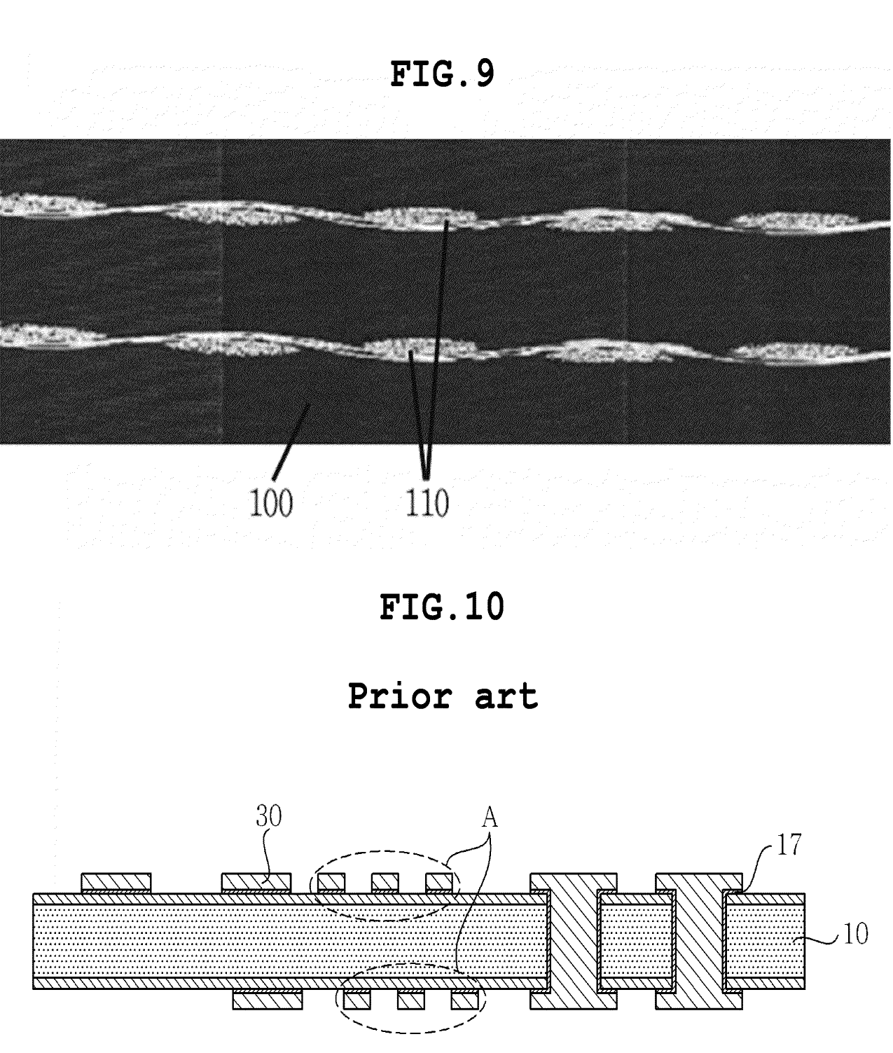

In addition, as described above, when two sheets of prepregs including the resin layer having a desired thickness formed on both surfaces of the glass fiber fabric are stacked, an insulating layer 100 in which two stopper layers for trench formation, that is, upper and lower stopper layers 110 for trench formation are disposed may be manufactured, as shown in FIG. 9.

Likewise, it will be obvious that an insulating layer 100 including at least three stopper layers 110 for trench formation may be manufactured by stacking at least three prepregs.

Here, when at least three stopper layers 100 for trench formation are disposed, a stopper layer 110 for trench formation disposed at the center except for stopper layers 110 for trench formation that are close to the surfaces of the insulating layer 100 may serve as a rigidity member for preventing warpage of a substrate.

Then, as shown in FIG. 3, trenches 100a exposing the stopper layers 110 for trench formation are processed in the insulating layer including the stopper layers 110 for trench formation disposed in an inner portion thereof.

Here, an operation of processing the trenches 100a may be performed by a laser drill by a laser beam. The laser drill may be any one of a CO₂ laser, a YAG laser, and a pulse UV excimer laser, without being specifically limited thereto.

Meanwhile, the trenches 100a may be processed by an imprinting mold rather than the laser drill.

After the trenches 100a are processed, via holes 100b penetrating through the stopper layers 110 for trench formation are processed, as shown in FIG. 4.

Here, the via holes 100b may be processed by a laser drill using a laser beam or a mechanical drill.

The laser drill may be any one of a CO₂ laser, a YAG laser, and a pulse UV excimer laser, and the mechanical drill may be a CNC drill, without being specifically limited thereto.

Although FIGS. 3 and 4 show a case in which the via holes 100b are processed after the trenches 100a are processed, the trenches 100a may be processed after the via holes 100b is first processed or the via holes 100b and the trenches 100a may be simultaneously processed by a plurality of lasers.

In addition, as described above, the trenches 100a may be processed by the laser drill or the imprinting mold, and the via holes 100b may be processed by the laser drill of the mechanical drill. When both of the trenches 100a and the via holes 100b are processed by the laser drill, the power and the number of shot of the laser beam applied to each of the trenches 100a and the via holes 100b need to be controlled.

For example, according to the preferred embodiment of the present invention, a lower power (for example, a power by which the stopper layers 110 for trench formation will not be penetrated through) may be used in the case of processing the trenches 100a than in the case of processing the via holes 100b.

In addition, a higher power (for example, a power by which the stopper layers 110 for trench formation will be penetrated through) may be used in the case of processing the via holes 100b than in the case of processing the trenches 100a.

In addition, as shown in FIG. 4, the via hole 100b having a sandglass shape in which a central portion thereof has a diameter smaller than those of inlet portions provided at upper and lower portions thereof may be processed through one shot for each of upper and lower surfaces of the insulating layer 100, that is, the total of two shots.

Here, the reason that the via hole 100b is processed to have the sandglass shape has been described in detail in a description of the above-mentioned structure. Therefore, a description of the reason will be omitted.

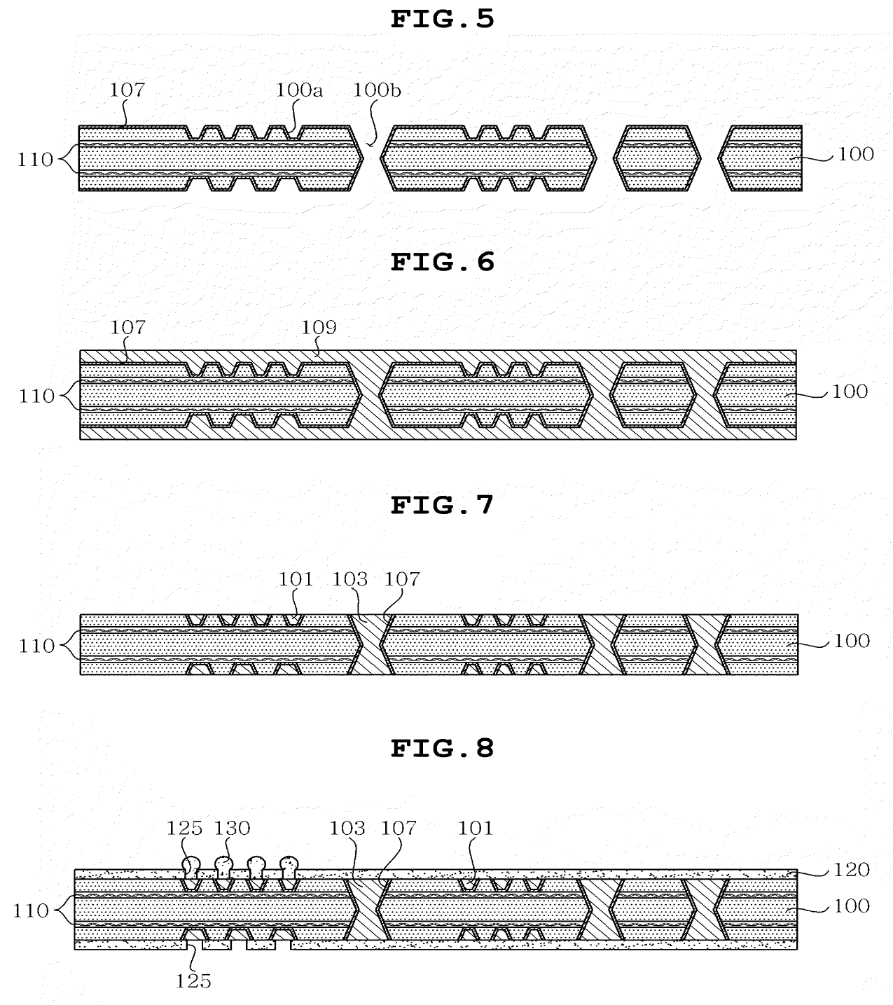

Next, as shown in FIG. 5, a seed layer 107 is formed by performing an electroless plating process on the insulating layer 100 and inner portions of the trenches 100a and the via holes 100b.

Here, the seed layer 107 is formed in order to perform electroplating for forming a plating layer 109 in a subsequent process.

Next, as shown in FIG. 6, the plating layer 109 is formed by performing an electroplating process on the insulating layer 100 and the trenches 100a and the via holes 100b on which the seed layer 107 is formed.

Then, as shown in FIG. 7, circuit patterns 101 and vias 103 are formed by removing the plating layer 109 excessively formed on the upper layer 100.

Here, the plating layer 109 is removed through chemical polishing, mechanical polishing, or chemical mechanical polishing, without being specifically limited thereto.

In addition, the plating layer 109 may be removed by performing a polishing process twice. That is, after a first polishing process of partially removing the plating layer 109 in a thickness direction thereof is performed, a second polishing process of removing a remaining plating layer 109 so that a surface of the insulating layer 100 is exposed, thereby forming the circuit patterns 101 and the vias 103 insulated from each other may be performed.

Here, the first and second polishing processes may be performed by different polishing schemes, without being specifically limited thereto.

As described above, although the preferred embodiment of the present invention describes a case in which the circuit patterns 101 and the vias 103 are formed by performing the plating process, the circuit patterns 101 and the vias 103 may also be formed through other processes, for example, a paste filling process, without being specifically limited thereto.

Next, as shown in FIG. 8, a solder resist layer 120 having openings 125 exposing some of the circuit patterns 101 is formed on the insulating layer 100, and external connection terminals are formed on the circuit patterns 101 exposed by the openings 125.

According to the preferred embodiment of the present invention, an operation of forming the solder resist layer 120 having the openings 125 may include forming the solder resist layer 120 on the insulating layer 100, disposing a mask (not shown) in which portions corresponding to the openings 125 are patterned on the solder resist layer 120, removing the solder resist corresponding to the openings 125 using a photolithography method or a laser method including exposure and development processes, and removing the mask (not shown).

Here, when the solder resist is a film, it may be formed on the insulating layer 100 through a vacuum lamination process, and when the solder resist is an ink, it may be generally formed thereon through a screen printing scheme, a roll coating scheme, a curtain coating scheme, a spray scheme, and the like.

Here, each of the schemes of forming the solder resist is widely known in the art. Therefore, a description thereof will be omitted.

In addition, the external connection terminal 130 may be a solder ball.

With the method of manufacturing the printed circuit board as described above, the trenches are formed in the insulating layer to form the intagliated circuit patterns, such that a micro circuit pattern is easily implemented and adhesion between the insulating layer and the circuit pattern is increased, thereby making it possible to prevent loss of the circuit due to a delamination phenomenon of the circuit pattern.

In addition, since the micro circuit pattern may be implemented, a circuit that has been formed over two layers is formed in a single layer, such that the number of layers in the substrate is reduced, thereby making it possible to simplify a process and miniaturize a product.

As described above, according to the preferred embodiments of the present invention, the trenches are processed in the insulating layer to form the circuit patterns, such that a micro circuit pattern is easily implemented and adhesion between the insulating layer and the circuit pattern is increased, thereby making it possible to prevent loss of the circuit due to a delamination phenomenon of the circuit pattern.

In addition, according to the preferred embodiments of the present invention, since the micro circuit pattern may be implemented, a circuit that has been formed over two layers is formed in a single layer, such that the number of layers in the substrate is reduced, thereby making it possible to simplify a process and miniaturize a product.

Further, according to the preferred embodiments of the present invention, the stopper layers for trench formation are disposed in the inner portion of the insulating layer to process the trenches having substantially the same depths, thereby making it possible to form uniform circuit patterns.

Although the preferred embodiments of the present invention have been disclosed for illustrative purposes, they are for specifically explaining the present invention and thus a printed circuit board and a method of manufacturing the same according to the present invention are not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A printed circuit board comprising:
an insulating layer including a stopper layer for trench formation disposed in an inner portion thereof and trenches formed to expose the stopper layer for trench formation; and
circuit patterns formed in the trenches.

2. The printed circuit board as set forth in claim 1, wherein the stopper layer for trench formation is disposed in a length direction of the insulating layer.

3. The printed circuit board as set forth in claim 1, wherein the stopper layer for trench formation is disposed in plural.

4. The printed circuit board as set forth in claim 1, wherein the stopper layer for trench formation is made of a glass fiber fabric.

5. The printed circuit board as set forth in claim 1, wherein the insulating layer further includes vias formed therein, the vias penetrating through the stopper layer for trench formation.

6. The printed circuit board as set forth in claim 5, wherein the via has a sandglass shape.

7. The printed circuit board as set forth in claim 1, further comprising a solder resist layer formed on the insulating layer and having openings exposing some of the circuit patterns.

8. The printed circuit board as set forth in claim 7, further comprising external connection terminals formed on the circuit patterns exposed by the openings.

9. The printed circuit board as set forth in claim 8, wherein the external connection terminal is a solder ball.

10. The printed circuit board as set forth in claim 1, wherein the circuit pattern is formed of a plating layer.

11. A method of manufacturing a printed circuit board, the method comprising:
preparing an insulating layer including a stopper layer for trench formation disposed in an inner portion thereof;
forming trenches exposing the stopper layer for trench formation in the insulating layer; and
forming circuit patterns in the trenches.

12. The method as set forth in claim 11, wherein the forming of the trenches is performed by a laser.

13. The method as set forth in claim 12, wherein the laser is any one of a CO₂ laser and a YAG laser.

14. The method as set forth in claim 11, wherein the forming of the trenches further includes forming via holes penetrating through the stopper layer for trench formation in the insulating layer, and
the forming of the circuit patterns in the trenches further includes forming vias in the via holes.

15. The method as set forth in claim 14, wherein the trenches and the via holes are simultaneously formed, and the circuit patterns and the vias are simultaneously formed.

16. The method as set forth in claim 14, wherein the via holes are formed before or after the forming of the trenches, and the circuit patterns and the vias are simultaneously formed.

17. The method as set forth in claim 14, wherein the forming of the via holes is performed by any one of a CO₂ laser, a YAG laser, and a CNC drill.

18. The method as set forth in claim 11, wherein the forming of the circuit patterns in the trenches includes:
forming a plating layer on the insulating layer and the trenches by performing a plating process; and
forming circuit patterns by removing the plating layer excessively formed on the insulating layer.

19. The method as set forth in claim 18, wherein the removing of the plating layer is performed through chemical polishing, mechanical polishing or chemical mechanical polishing.

20. The method as set forth in claim 11, wherein the stopper layer for trench formation is made of a glass fiber fabric.
